(19) United States
(12) Patent Application Publication
(10) Pub. No.: US 2006/0128069 A1
(43) Pub. Date: Jun. 15, 2006

(54) Package structure with embedded chip and method for fabricating the same

(75) Inventor: Shih-Ping Hsu, Hsin-chu (TW)

Correspondence Address: EDWARDS & ANGELL, LLP, P.O. BOX 55874, BOSTON, MA, 02205, US

(73) Assignee: Phoenix Precision Technology Corporation, Hsin-Chu (TW)

(21) Appl. No.: 11/267,483

(22) Filed: Nov. 3, 2005

(30) Foreign Application Priority Data
Dec. 10, 2004 (TW) 093138305

(51) Int. Cl. H01L 21/48; H01L 21/50

(52) U.S. Cl. 438/124; 438/126

(57) ABSTRACT

A package structure with embedded chip and a fabrication method thereof are proposed. A carrier board is provided, and at least one semiconductor chip is mounted on the carrier board. A core board having a cavity corresponding in position to the semiconductor chip and an insulating layer are pressed on the carrier board, such that the semiconductor chip is received in the cavity of the core board, and the insulating layer is filled in a gap between the cavity of the core board and the semiconductor chip so as to fix the semiconductor chip in the cavity. A circuit patterning process is performed on the insulating layer to form a circuit layer electrically connected to the semiconductor chip. A passive component can be mounted in the core board and electrically connected to the circuit layer. Thereby, the fabrication of a chip carrier and the chip packaging process are integrated.

### FIELD OF THE INVENTION

The present invention relates to a package structure with an embedded chip and a method for fabricating the same, and more specifically, to a package structure having the chip adhered to a heat dissipating fin for building-up circuits layer by layer and a method for fabricating the same.

### BACKGROUND OF THE INVENTION

With the development of the semiconductor package technology, various package types are developed for semiconductor device, wherein ball grid array (BGA) is an advanced semiconductor package technology, characterized in a substrate is employed to carry the semiconductor chip, and self-alignment technology is employed to mount a plurality of solder balls aligned in grid on an back surface of the substrate, so that more I/O connections can be accommodated in the carrier board of the semiconductor chip having the same area, therefore meeting the need of high integration; the whole package unit can thus be soldered and electrically connected to external circuit board via the solder balls.

However, under the requirements for multi-function and good performance to electronic products, particularly under high frequency, high speed operation, ordinary BGA package is gradually faced with technical bottom neck. FBGA package, instead, is currently becoming popular in high class products because of its efficiently improved electrical and mechanical properties. One factor why FBGA package is not widely used in general electronic products is its high cost; in addition, a plurality of passive components, such as capacitors, is cooperatively needed to be employed in the course of packaging to improve electrical transmitting properties thereof. Another factor is that the passive components are electrically connected via SMT technology, the conductive trace between which and the IC chip is relative long, so as to degrade whose electrical properties. Additionally, solder reflow has to be employed in the arrangement of the passive components, particularly under the lead-free requirement of environment protection, SMT technology is faced with challenge, and the substrate may suffer high temperature damage because of repeating solder reflow, which badly damage the quality and reliability of the semiconductor package.

In addition, in the fabricating of conventional semiconductor components, the chip carriers of the semiconductor components are firstly fabricated by chip carriers manufacturer (such as electrical circuit board manufacturer); after that, the chip carriers are transferred to the semiconductor package manufacturers to be performed with fabricating procedures such as chip attaching, molding and ball mounting; last, the semiconductor components having electronic functions needed by the customers can be achieved; wherein different manufacturers (such as chip carriers manufacturers and semiconductor package manufactures) are involved in various phases, thus the practical fabricating thereof is not only complicated, but also not easy to integrate the interfaces thereof; furthermore, if function design is required to be altered by the customers, much more complicated operation of modification and integration to the layers may be involved which does not have alteration flexibility and economical effect.

### SUMMARY OF THE INVENTION

Regarding the drawbacks of the above mentioned conventional technologies, the primary objective of the present invention is to provide a package structure with embedded chip and method for fabricating the same, wherein at least one semiconductor chip and a component are embedded in a carrier board, and directly electrically connected, therefore shortening the conductive trace between the components for improving the electrical properties.

Another objective of the present invention is to provide a package structure with embedded chip and method for fabricating the same, which embeds a chip and a passive component in a carrier for integrating and modulating; and which directly electrically connects and builds-up layers for simplifying the fabricating and saving fabricating cost, simultaneously decreasing the use of solder material for meeting the requirement of environment protecting.

Still another objective of the present invention is to provide a package structure with embedded chip and method for fabricating the same, wherein an insulating layer is employed to secure the semiconductor chip, and to be the material for circuit fabricating, therefore saving material and lowering fabricating cost.

Still another objective of the present invention is to provide a package structure with embedded chip and method for fabricating the same, wherein a carrier board serves as a supporting and heat dissipating member for improving the heat dissipating effect of the chip.

Still another objective of the present invention is to provide a package structure with embedded chip and method for fabricating the same, which integrates both of the fabricating technology of chip carrier board and the packaging technology of chips for simplifying the problems of integrating the fabricating and the interface thereof.

In accordance with the above and other objectives, the present invention proposes a method for fabricating a package structure with embedded chip, a preferred embodiment of the present invention comprises: providing a carrier board, attaching at least one semiconductor chip on a surface of the carrier board; providing a core board and an insulating layer, the core board predefining a cavity corresponding in position to the semiconductor chip, the insulating layer and core board pressed on the carrier board, the insulating layer is filled in a gap between the cavity of the core board and the semiconductor chip so as to fix the semiconductor chip in the cavity of the core board; and performing circuit process on the insulating layer to form a circuit layer. Wherein, passive components can be in advance arranged on the core board, therefore in the course of performing circuit process, the circuit layer can be both electronic connected to the semiconductor chip and the passive components, thus improving the electrical properties. A circuit build-up process can be further performed on the circuit layer to form a circuit build-up structure on the core board receiving the semiconductor chip therein. In addition, the carrier board forms an adhesive layer on a surface thereof, and the semiconductor chip and the core board are arranged on the adhesive layer; the carrier board forms the adhesive layer only on a position for attaching the semiconductor chip.

Additionally, the present invention discloses a package structure with embedded chip, comprising: a carrier board; a core board arranged on the carrier board, the core board defining a cavity running through the upper and lower surfaces thereof; at least one semiconductor chip attached on the carrier board and received in the cavity of the core board; a plurality of passive components arranged on the core board; at least one circuit structure formed on the semiconductor chip and the core board, and electrically connecting the semiconductor chip and the passive components, wherein the semiconductor chip can be positive or passive chip.

Consequently, the package structure with embedded chip and method for fabricating the same of the present invention adheres the semiconductor chip on the carrier board, arranges the core board having predefined cavity on the carrier board, and receives the semiconductor chip in the cavity of the core board; so that the insulating layer used in the following process is filled in the gap between the semiconductor chip and the cavity of the core board. The insulating layer is used as the material fixing the semiconductor chip and circuit process, therefore saving the material, lowering the fabricating cost, and combining the processes to simplify the fabricating procedure. In addition, passive components can be in advance embedded in the core board so that the circuit layer can be directly electrically connected to the passive components at the same time electrically connected to the semiconductor chip, therefore decreasing the use of soldering tin in the course of electrically connecting the passive components and the solder reflow times to meet the requirement for protecting environment and improving the reliability of the fabricating procedure. Furthermore, the present invention employs the carrier board as a supporting member and a heat dissipating member; simultaneously integrates the fabricating of the carrier board and the packaging of the chip thus simplifying the integration of the fabricating procedure and the interface.

### BRIEF DESCRIPTION OF THE DRAWINGS

FIGS. 1A to 1I are section views of the package structure with embedded chip and method for fabricating the same in accordance with a first embodiment of the present invention;

FIGS. 2A to 2D are section views of the package structure with embedded chip and method for fabricating the same in accordance with a second embodiment of the present invention; and

FIGS. 3A to 3D are section views of a package structure with embedded chip and method for fabricating the same in accordance with a third embodiment of the present invention.

### DETAILED DESCRIPTION OF THE PREFERRED EMBODIMENTS

The following embodiments are used to describe the present invention; those skilled in the art can easily understand other advantages and functions of the present invention via the contents disclosed in the description. Various embodiments can be employed in the present invention; and the detail of the description can be based on and employed in various points of view, which can be modified within the scope of the present invention.

The following embodiments are used for further detailing the feature of the present invention, which shall not be regarded as a limitation to the scope of the present invention.

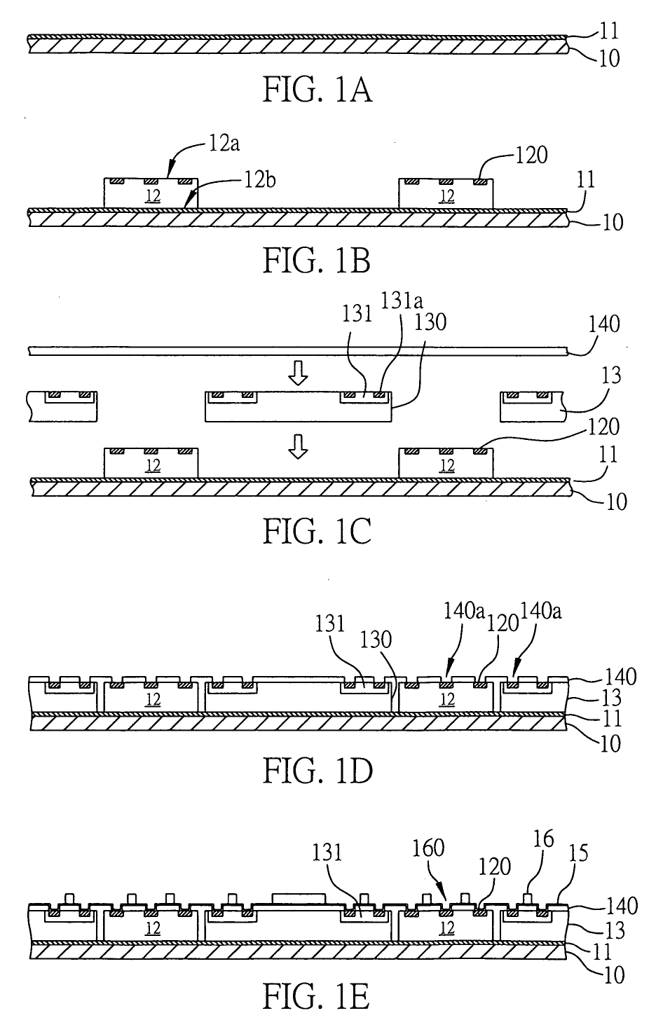

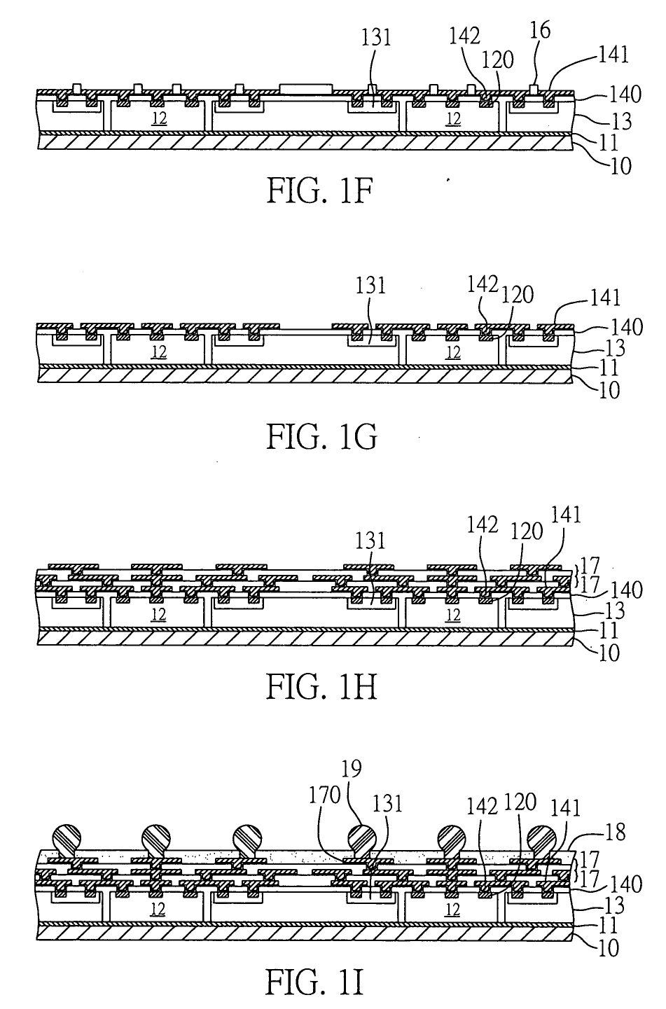

FIGS. 1A to 1I are section views of the package structure with embedded chip and method for fabricating the same in accordance with a first embodiment of the present invention.

As illustrated in FIG. 1A, a carrier board 10 is provided, and an adhesive layer 11 is formed on a surface of the carrier board 10. The carrier board 10 can be made of materials having good heat conductivity and high rigidity, such as copper metal, copper alloy, aluminum metal, aluminum alloy, copper/nickel alloy, carbon fiber, stainless steel, ceramic or aluminum/magnesium alloy, and the carrier board 10 is performed with a surface roughening process to improve the adhesive force between the surface thereof and the adhesive layer 11. Additionally, an oppositely concavo-convex structure can be formed on the outer surface (not shown) of the carrier board 10, for increasing the effective heat dissipating are and heat dissipating efficiency of the carrier board 10. The adhesive layer 11 can be made of epoxy, tape, ABF (Ajinomoto build-up film), aramid and so on.

As illustrated in FIG. 1B, a semiconductor chip 12 is directly attached to a predetermined position on the adhesive layer 11, wherein the semiconductor chip 12 is attached to the adhesive layer 11 on its non-active surface 12b, the active surface 12a of the semiconductor chip 12 comprises a plurality of electrically connecting pads 120, in addition, the semiconductor chip 12 can be selected to be positive or passive chip, whose number is not limited as illustrated in figure wherein at least one of which is employed in the present embodiment.

As illustrated in FIG. 1C, a core board 13 and an insulating layer 140 are provided, and the core board 13 predefines at least one cavity 130 running through the upper and lower surfaces thereof. The core board 13 is firstly attached to the carrier board 10 via the adhesive layer 11, and the insulating layer 140 is then heated and pressed on the core board 13; or the core board 13, insulating layer 140 and the carrier board 10 is heated and pressed together, such that the semiconductor chip 12 is received in the cavity 130 of the core board 13, and the insulating layer 140 is filled in a gap between the cavity 130 and the semiconductor chip 12, so as to fix the semiconductor chip 12 in the cavity 130 of the core board 13. The core board 13 serves as an insulating board or a circuit board having preformed circuit layer; and a plurality of passive components 131 (such as resistors, capacitors and inductances) having electrical contacts 131a exposed on the surface thereof can be in advance arranged on the core board 13. The insulating layer 140 can be made of photosensitive material or non-photosensitive material, such as ABF (Ajinomoto build-up film), epoxy, PTFE and so on.

As illustrated in FIG. 1D, a plurality of openings 140a is defined (employing methods such as laser drilling, exposure, development and so on) in the insulating layer 140, such that the electrical contacts 131a of the passive components 131 and the electrically connecting pads 120 of the semiconductor chip 12 are exposed.

As illustrated in FIG. 1E, a conductive layer 15 is formed on the insulating layer 140 and the surface of the electrical contacts 131a of the passive components 131 and the electrically connecting pads 120 of the semiconductor chip 12; a resist layer 16 is formed on the conductive layer 15; the resist layer 16 defines a plurality of patterning openings 160 to expose a part of the conductive layer 15 covered beneath, wherein openings 160 of the part of the resist layer 16 corresponds to the openings 140a of the insulating layer 140. The conductive layer 15 is mainly used as a electrically conductive trace needed in the following detailed metal layer electroplating process, which can be made of conductive macromolecule material.

As shown in FIG. 1F, an electroplating process is performed, for forming a circuit layer 141 on the conductive layer exposed in the openings 160 of the resist layer 16, and conductive vias 142 in the openings 140a of the insulating layer 140. The circuit layer 11 is thus electrically connected to the electrically connecting pads 120 and the electrical contacts 131 a of the passive components 131 via the conductive vias 142 formed in the insulating layer 140; that is, the semiconductor chip 12 and the passive component 131 can be electrically connected to external environment via the conductive vias 142 and the circuit layer 141.

As illustrated in FIG. 1G, the resist layer 16 and the part of the conductive layer 15 covering thereon are removed.

As illustrated in FIG. 1H, a circuit build-up process can be further performed, such that a circuit build-up structure 17 is formed on the core board 13 receiving the semiconductor chip 12 therein; and the circuit build-up structure 17 is electrically connected to the beneath circuit layer 141, so that the semiconductor chip 12 and the passive component 131 can be electrically connected to external conductive elements via the circuit layer 141 and the circuit build-up structures 17.

As illustrated in FIG. 1I, a solder mask layer 18 is then formed on an outer surface of the circuit build-up structure 17; the solder mask layer 18 defines a plurality of openings to expose the electrically connecting pads 170 on the outer surface of the circuit build-up structure 17; a plurality of conductive elements 19, such as solder balls or conductive pillars, is formed on the electrically connecting pads 170 on the outer surface of the circuit build-up structure 17, so that the semiconductor package can be electrically connected to external devices.

Consequently, the package structure with embedded chip achieved from the above process comprises a carrier board 10; a core board 13 arranged on the surface of the carrier board, the core board 13 defining a cavity 130 running through the upper and lower surfaces thereof; at least one semiconductor chip 12 arranged on the carrier board 10 and received in the cavity 130 of the core board 13; a plurality of passive components 131 arranged on the core board 13; and at least one circuit layer 141 formed on the core board 13 receiving the semiconductor chip 12 therein, the circuit layer 141 electrically connecting the semiconductor chip 12 and the passive components 131. In addition, the semiconductor package structure can further comprise a circuit build-up structure 17 and conductive elements 19 arranged thereon.

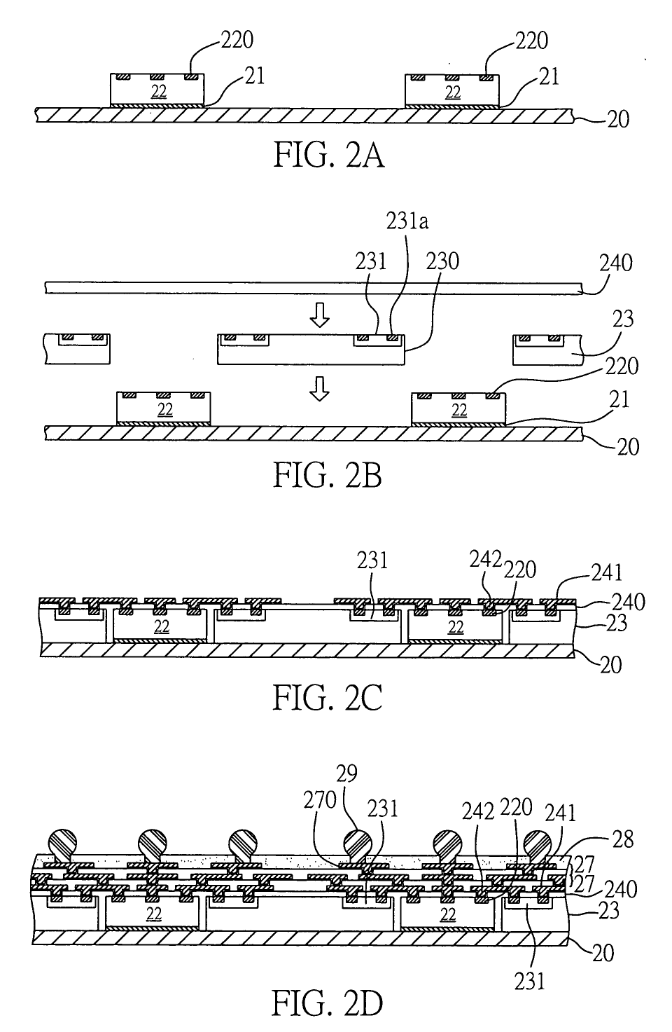

FIGS. 2A to 2D are section views of the package structure with embedded chip and method for fabricating the same in accordance with a second embodiment of the present invention.

As illustrated in FIG. 2A, a carrier board 20 is provided, an adhesive layer 21 is formed o the surface of the carrier board 20 corresponding to a semiconductor chip 22 to be connected thereto, such that the semiconductor chip 22 having electrically connecting pads 220 is connected to the carrier board 20. The carrier board 20 can be made of materials having good heat conductivity and high rigidity, such as copper metal, copper alloy, aluminum metal, aluminum alloy, stainless steel, copper/nickel alloy, carbon fiber, ceramic or aluminum/magnesium alloy, and the carrier board 20 is performed with a surface roughening process to improve the adhesive force between the surface thereof; and the semiconductor chip 22 can be positive or passive chip.

As illustrated in FIG. 2B, a core board 23 and an insulating layer 240 are provided. The core board 23 defines a cavity 230 corresponding to the position of the semiconductor chip 22. The core board 23 is firstly arranged on the surface of the carrier board 10; the insulating layer 240 is then heated and pressed on the core board 23, and the insulating layer 240 is melted and filled in a gap between the cavity 230 of the core board 23 and the semiconductor chip 22, so as to fix the semiconductor chip 22 in the cavity 230 of the core board 23. The core board 23 can be an insulting board or a circuit board having preformed circuits. Additionally, the core board 23 connects a plurality of passive components 231 having electrical contacts 231a.

As illustrated in FIG. 2C, a circuit patterning process is performed to form a circuit layer 241 on the surface of the insulating layer 240. The insulating layer 240 defines conductive vias 242 corresponding to the electrically connecting pads 220 of the semiconductor chip 22 and the electrical contacts 231a, such that the circuit layer 241 is electrically connected to the semiconductor chip 22 and the passive components 231 via the conductive vias 242. The circuit patterning process is similar to the first embodiment, which will be not detailed herein.

As illustrated in FIG. 2D, a circuit build-up process is performed to form a circuit build-up structure 27. A solder mask layer 28 is formed on the outer surface of the circuit build-up structure 27; the solder mask layer 28 defines a plurality of openings to expose the electrically connecting pads 270 on the outer surface of the circuit build-up structure 27, so that a plurality of conductive elements 29 is formed on the electrically connecting pads 270 on the outer surface of the circuit build-up structure 27 for electrically connecting external devices.

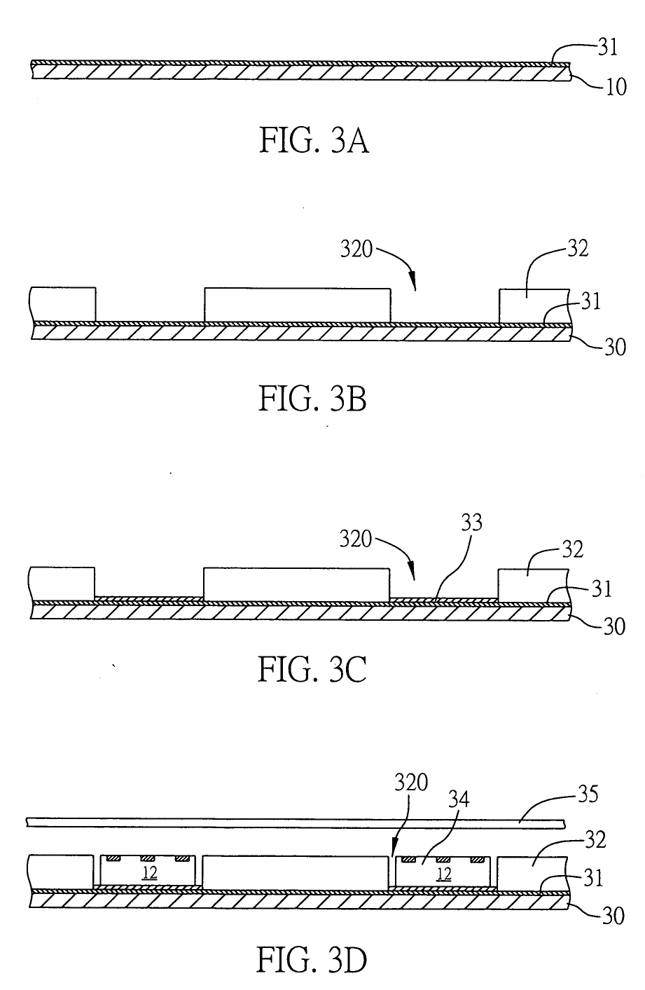

FIGS. 3A to 3D are section views of a package structure with embedded chip and method for fabricating the same in accordance with a third embodiment of the present invention, which is different to the first embodiment in that the core board is firstly arranged, and the semiconductor chip is arranged afterwards.

As illustrated in FIG. 3A, a carrier board 30 is provided, a first adhesive layer 31 is formed on the surface of the carrier board 30.

As illustrated in FIG. 3B, a core board 32 having at least one cavity 320 is arranged on a predetermined position of the first adhesive layer 31.

As illustrated in FIG. 3C, a second adhesive layer 33 is formed in the cavity 320 of the core board 32.

As illustrated in FIG. 3D, the semiconductor chip 34 is attached on the second adhesive layer 33 in the cavity 320 of the core board 32. An insulating layer 35 is provided to be heated and pressed on the core board 32, and the insulating layer is filled in a gap between the cavity 320 and the semiconductor chip 34, so as to fix the semiconductor chip 34 in the cavity 320 of the core board 320. A following circuit build-up process is similar to the first embodiment, which will not be detailed herein.

In the package structure with embedded chip and method for fabricating the same of the present invention, the feature is to press the insulating layer on the surface of the core board, and the insulating layer is filled in the gap between the cavity and the semiconductor chip before it is solidified, the semiconductor chip can be thus fixed in the cavity after the insulating layer is solidified. The problems of filling adhesive material can be solved by employing the insulating layer to be the adhesive material; and the fabricating procedure is simplified by combining the following circuit patterning process to the photosensitive or non-photosensitive insulating layer together.

In addition, the insulting layer is used to fix the semiconductor chip and to perform the following circuit patterning process, which has dual functions and avoids from using two kinds of materials, which use a single material to provide two different functions so as to save the cost of materials.

Furthermore, in the present invention, the carrier board is used as a supporting member; the semiconductor chip is received in a groove formed between the carrier board and the core board so as to solve the problem of conventional technology whose substrate directly defines a cavity in a surface thereof to receive the semiconductor chip; at the same time, a thin and small semiconductor package is thus achieved.

Consequently, the package structure with embedded chip and method for fabricating the same of the present invention adheres the semiconductor chip on the carrier board, arranges the core board having predefined cavity on the carrier board, and receives the semiconductor chip in the cavity of the core board; so that the insulating layer used in the following process is filled in the gap between the semiconductor chip and the cavity of the core board. The insulating layer is used as the material fixing the semiconductor chip and circuit process, therefore saving the material, lowering the fabricating cost, and combining the processes to simplify the fabricating procedure. In addition, passive components can be in advance embedded in the core board so that the circuit layer can be directly electrically connected to the passive components at the same time electrically connected to the semiconductor chip, therefore decreasing the use of soldering tin in the course of electrically connecting the passive components and the solder reflow times to meet the requirement for protecting environment and improving the reliability of the fabricating procedure. Furthermore, the present invention employs the carrier board as a supporting member and a heat dissipating member; simultaneously integrates the fabricating of the carrier board and the packaging of the chip thus simplifying the integration of the fabricating procedure and the interface.

It should be apparent to those skilled in the art that the above description is only illustrative of specific embodiments and examples of the present invention. The present invention should therefore cover various modifications and variations made to the herein-described structure and operations of the present invention, provided they fall within the scope of the present invention as defined in the following appended claims.

What is claimed is:

1. A method for fabricating a package structure with embedded chip, comprising:
providing a carrier board and mounting a semiconductor chip on the carrier board, the semiconductor chip having electrically connecting pads;
providing a core board and an insulating layer wherein the core board is formed with a cavity corresponding in position to the semiconductor chip, and pressing the insulating layer and the core board on the carrier board, wherein the insulating layer is filled in a gap between the cavity of the core board and the semiconductor chip so as to fix the semiconductor chip in the cavity of the core board; and
performing a circuit patterning process on the insulating layer to form a circuit layer on a surface of the insulating layer, wherein the circuit layer is electrically connected to the electrically connecting pads of the semiconductor chip.

2. The method for fabricating a package structure with embedded chip of claim 1, wherein the core board is firstly attached to the carrier board via an adhesive layer, and then the insulating layer is pressed on the core board.

3. The method for fabricating a package structure with embedded chip of claim 1, wherein the core board, the insulating layer and the carrier board are heated and pressed together.

4. The method for fabricating a package structure with embedded chip of claim 1, wherein the circuit patterning process comprises:
forming openings in the insulating layer to expose the electrically connecting pads of the semiconductor chip;
forming a conductive layer on the surface of the insulating layer and the electrically connecting pads of the semiconductor chip;
performing an electroplating process after forming a patterned resist layer on the conductive layer, so as to form the circuit layer and conductive vias on the conductive layer; and
removing the resist layer and a part of the conductive layer covered thereby.

5. The method for fabricating a package structure with embedded chip of claim 1, wherein the circuit layer is electrically connected to the electrically connecting pads of the semiconductor chip by the conductive vias.

6. The method for fabricating a package structure with embedded chip of claim 1, further comprising performing a circuit build-up process to form a circuit build-up structure.

7. The method for fabricating a package structure with embedded chip of claim 6, further comprising disposing conductive elements on an outer surface of the circuit build-up structure so as to electrically connect the semiconductor chip to an external device via the conductive elements.

8. The method for fabricating a package structure with embedded chip of claim 1, wherein the carrier board is made of a material having good heat conductivity and high rigidity, which is selected from the group consisting of copper metal, copper alloy, aluminum metal, aluminum alloy, stainless steel, copper/nickel alloy, carbon fiber, ceramic and aluminum-magnesium alloy.

9. The method for fabricating a package structure with embedded chip of claim 1, wherein the carrier board is performed with a surface roughening process to improve adhesive force thereof.

10. The method for fabricating a package structure with embedded chip of claim 1, wherein the semiconductor chip is attached to the carrier board via an adhesive layer entirely formed on the carrier board.

11. The method for fabricating a package structure with embedded chip of claim 1, wherein the semiconductor chip is attached to the carrier board via an adhesive layer partly formed on the carrier board.

12. The method for fabricating a package structure with embedded chip of claim 1, wherein the core board is one of an insulating board and a circuit board having preformed circuits.

13. The method for fabricating a package structure with embedded chip of claim 1, wherein the core board is mounted with a plurality of passive components having electrical contacts.

14. The method for fabricating a package structure with embedded chip of claim 13, wherein the passive components are electrically connected to the circuit layer by conductive vias and are further electrically connected outwardly.

15. A package structure with embedded chip, comprising:
a carrier board;
a core board mounted on the carrier board and formed with a cavity penetrating therethrough;
a plurality of passive components having electrical contacts and mounted on the core board;
at least one semiconductor chip having electrically connecting pads, the semiconductor chip being mounted on the carrier board and received in the cavity of the core board;
at least one insulating layer formed on the semiconductor chip and the core board; and
at least one circuit layer formed on the insulating layer, the circuit layer being electrically connected to the electrically connecting pads of the semiconductor chip and the electrical contacts of the passive components by a plurality of conductive vias formed in the insulating layer.

16. The package structure with embedded chip of claim 15, further comprising at least one circuit build-up structure formed on the circuit layer and the insulating layer.

17. The package structure with embedded chip of claim 16, further comprising a plurality of conductive elements formed on the circuit build-up structure.

18. The package structure with embedded chip of claim 15, wherein an adhesive layer is formed entirely on a surface of the carrier board, for attaching the semiconductor chip and the core board to the surface of the carrier board.

19. The package structure with embedded chip of claim 15, wherein a first adhesive layer is formed on a surface of the carrier board, for attaching the core board to the surface of the carrier board, and a second adhesive layer for attaching the semiconductor chip is formed in the cavity of the core board.

20. The package structure with embedded chip of claim 15, wherein a surface of the carrier board is roughened to improve adhesive force thereof.

21. A method for fabricating a package structure with embedded chip, comprising:
providing a carrier board and forming a first adhesive layer on a surface of the carrier board;
providing a core board, forming a cavity through the core board, and pressing the core board on the carrier board;
forming a second adhesive layer in the cavity of the core board;
mounting a semiconductor chip in the cavity of the core board;
providing an insulating layer and pressing the insulating layer on the core board, wherein the insulating layer is filled in a gap between the cavity of the core board and the semiconductor chip so as to fix the semiconductor chip in the cavity of the core board; and
performing a circuit patterning process on the insulating layer so as to form a circuit layer on a surface of the insulating layer, wherein the circuit layer is electrically connected to electrically connecting pads of the semiconductor chip.

22. The method for fabricating a package structure with embedded chip of claim 21, wherein the circuit patterning process comprises:
forming openings in the insulating layer to expose the electrically connecting pads of the semiconductor chip;
forming a conductive layer on the surface of the insulating layer and the electrically connecting pads of the semiconductor chip;
performing an electroplating process after forming a patterned resist layer on the conductive layer, so as to form the circuit layer and conductive vias on the conductive layer; and
removing the resist layer and a part of the conductive layer covered thereby.

23. The method for fabricating a package structure with embedded chip of claim 21, wherein the circuit layer is electrically connected to the electrically connecting pads of the semiconductor chip by conductive vias.

24. The method for fabricating a package structure with embedded chip of claim 21, further comprising performing a circuit build-up process to form a circuit build-up structure.

25. The method for fabricating a package structure with embedded chip of claim 24, further comprising disposing conductive elements on an outer surface of the circuit build-up structure, so as to electrically connect the semiconductor package to an external device via the conductive elements.

26. The method for fabricating a package structure with embedded chip of claim 21, wherein the core board is one of an insulating board and a circuit board having preformed circuits.

27. The method for fabricating a package structure with embedded chip of claim 21, wherein the core board is mounted with a plurality of passive components having electrical contacts.

28. The method for fabricating a package structure with embedded chip of claim 27, wherein the passive components is electrically connected to the circuit layer via conductive vias and are further electrically connected outwardly.

29. The method for fabricating a package structure with embedded chip of claim 21, wherein the carrier board is performed with a surface roughening process to improve adhesive force thereof.
